(19) United States
(12) Patent Application Publication
(10) Pub. No.: US 2020/0387467 A1
(43) Pub. Date: Dec. 10, 2020

(54) OUTPUT DETERMINATION CIRCUIT

(71) Applicant: Mitsubishi Electric Corporation, Tokyo (JP)

(72) Inventors: Hirohide NOZAKI, Tokyo (JP); Yoshihiro OGAWA, Tokyo (JP)

(73) Assignee: Mitsubishi Electric Corporation, Tokyo (JP)

(21) Appl. No.: 16/960,746

(22) PCT Filed: Feb. 28, 2018
(86) PCT No.: PCT/JP2018/007634

§ 371 Date: Jul. 8, 2020

(51) Int. Cl. G06F 13/40; G06F 11/14; H03K 19/003

(52) U.S. Cl. CPC G06F 13/4022; H03K 19/003; G06F 11/142

(57) ABSTRACT

An output determination circuit is fabricated by a hard-wired scheme to execute an instruction via hardware connection. The output determination circuit determines an output signal of a Field Programmable Gate Array (FPGA) which operates according to logic information. The output determination circuit comprises a majority decision circuit. The majority decision circuit is connected to outputs of a plurality of FPGAs which perform the same operation. The majority decision circuit performs majority decision on the outputs of the plurality of FPGAs to determine outputs from the plurality of FPGAs as an output signal. The majority decision circuit is constituted of only logic operation elements.

### TECHNICAL FIELD

The present invention relates to a reliability of a Field Programmable Gate away (FPGA) which can reconfigure an internal logic circuit repeatedly.

### BACKGROUND ART

Apparatuses often employ dedicated Large-Scale Integration (LSI) such as an Application Specific Integrated Circuit (ASIC). In recent years, however, as the miniaturization of semiconductors progresses, the development costs have increased steeply. In a case where a production quantity is small, FPGAs are used oftener.

An FPGA is a device whose internal logic can be changed by a user. Although the FPGA has a higher product unit price than an ASIC, since it is a general-purpose LSI, no LSI development costs are incurred. Therefore, the FPGA is suitable for small-quantity multi-product production.

In the FPGA, when the power supply is turned on, data of logic circuit information from outside is stored in an internal configuration Random Access Memory (RAM). The internal logic of the FPGA is determined according to the logic circuit information. Therefore, in the FPGA, when data in the RAM of logic information changes, the logic circuit information changes, and a normal operation cannot be performed. To cope with this, FPGA manufacturers take measures such as mounting an error correction circuit on the RAM of the logical information. In recent years, the following issue has arisen that, as the miniaturization of FPGAs progresses, data in the RAM changes due to a software error caused by cosmic ray neutrons, and the logic circuit information of the FPGA does not perform originally intended operation. In view of this, a method is available according to which a plurality of logic circuits of the same type are provided, and determination is made on outputs from the plurality of logic circuits by a majority decision, so that the original operation is ensured.

In Patent Literature 1, a detection circuit which detects occurrence of an error is constituted not of an FPGA but of another radiation resistance enhanced ASIC. However, a radiation resistance enhanced ASIC is not completely free from the influence of cosmic radiation. In a case where a circuit in a radiation resistance enhanced ASIC uses a memory element such as a flip-flop, a possibility that data might be rewritten by cosmic radiation cannot be denied. Therefore, sometimes a software error cannot be avoided only by using a radiation resistance enhanced ASIC.

In Patent Literature 2, an FPGA is provided with a high-reliability mounting unit having strong software error resistance, and a detection circuit such as a majority decision circuit is mounted on the high-reliability mounting unit. According to Patent Literature 2, this prevents a RAM storing logic circuit information of the detection circuit from being changed by a software error. However, there is no description concerning a method that completely avoids a software error of the RAM in the high reliability mounting unit.

### CITATION LIST

### Patent Literature

Patent Literature 1: JP 2009-534738 A

Patent Literature 2: International Publication WO2015/045135

### SUMMARY OF INVENTION

### Technical Problem

In the conventional method, a measure against an occurrence of a software error is not sufficiently taken for a circuit that detects an occurrence of an error.

An objective of the present invention is even in a case where an operation of an FPGA is changed by a software error and the FPGA cannot perform a normal operation, to enable output of a normal signal because of the presence of another FPGA operating normally.

### Solution to Problem

An output determination circuit according to the present invention is fabricated by a hard-wired scheme to execute an instruction via hardware connection, and determines an output signal of an FPGA which operates according to logic information, the output determination circuit comprising

a majority decision circuit which is connected to outputs of a plurality of FPGAs that perform the same operation and which performs majority decision on the outputs of the plurality of FPGAs to determine the outputs from the plurality of FPGAs as the output signal, the majority decision circuit being constituted of only logic operation elements.

### Advantageous Effects of Invention

An output determination circuit according to the present invention is fabricated by a hard-wired scheme. The output determination circuit is provided with a majority decision circuit connected to outputs of a plurality of FPGAs performing the same operation. The majority decision circuit performs majority decision on outputs of the plurality of FPGAs to determine the outputs from the plurality of FPGAs as an output signal. The majority decision circuit is composed of only logic operation elements. Therefore, with the output determination circuit according to the present invention, determination on outputs of the plurality of FPGAs can be made by majority decision using a circuit free from a software error and an error due to a flip-flop. Hence, correct decision can be made on the outputs of the FPGAs.

### BRIEF DESCRIPTION OF DRAWINGS

FIG. 1 is a configuration diagram of a processing circuit according to Embodiment 1.

FIG. 2 is a flowchart of an output determination process by an output determination circuit according to Embodiment 1.

FIG. 3 is a configuration example of a majority decision circuit according to Embodiment 1.

FIG. 4 is a configuration example of a reconfiguration circuit according to Embodiment 1.

FIG. 5 is a configuration diagram of a processing circuit according to Embodiment 2.

FIG. 6 is a configuration example of a selector according to Embodiment 2.

FIG. 7 is a configuration diagram of a processing circuit according to Embodiment 3.

FIG. 8 is a configuration diagram of a processing circuit according to Embodiment 4.

### DESCRIPTION OF EMBODIMENTS

Embodiments of the present invention will now be described with referring to drawings. In the drawings, the same or equivalent portion is denoted by the same reference sign. In description of the embodiments, explanation on the same or equivalent portion is omitted or simplified as necessary.

### Embodiment 1

***Description of Configuration***

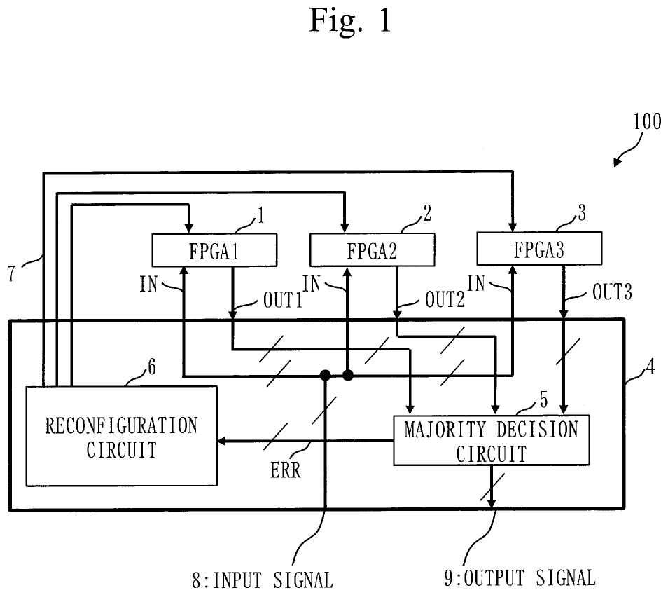

A processing circuit 100 according to the present embodiment will be described with referring to FIG. 1.

The processing circuit 100 according to the present embodiment is provided with a plurality of FPGAs and an output determination circuit 4 which determines an output signal 9 of the FPGAs. The plurality of FPGAs are: an FPGA1, an FPGA2, and an FPGA3. In the processing circuit 100 of the present embodiment, a majority decision is made with using the three FPGAs which perform the same operation. Although three FPGAs are used in the present embodiment, it suffices as far as a number of FPGAs is an odd number such as five, seven, and nine.

The processing circuit 100 is provided with the three FPGAs, that is, the FPGA1, the FPGA2, and the FPGA3 which operate according to logic information. The FPGA1, the FPGA2, and the FPGA3 are circuits that perform the same operation. The FPGA1, the FPGA2, and the FPGA3 need not be the same FPGA circuits as far as their FPGA input/output signals are the same.

An output determination circuit 4 is fabricated by a hard-wired scheme to execute an instruction via hardware connection. The output determination circuit 4, although it can be implemented by an ASIC, is not limited to an ASIC, and may be fabricated by any fabrication method as far as it can be fabricated in a hardware manner.

The output determination circuit 4 is a circuit that determines outputs of the FPGAs as the output signal 9 and detects an FPGA in which an error has occurred. The output determination circuit 4 is provided with a majority decision circuit 5 and a reconfiguration circuit 6.

The majority decision circuit 5 is connected to outputs of the plurality of FPGAs that perform the same operation. The majority decision circuit 5 performs majority decision on the outputs of the plurality of FPGAs to determine the outputs from the plurality of FPGAs as the output signal 9. The majority decision circuit 5 is constituted of only logic operation elements.

The majority decision circuit 5 outputs an error signal ERR that notifies in which FPGA an error has occurred among the plurality of FPGAs. That is, the majority decision circuit 5 is a circuit that decides on the outputs of the FPGA.

The reconfiguration circuit 6 acquires the error signal ERR from the majority decision circuit 5. Based on the error signal ERR, the reconfiguration circuit 6 outputs a reconfiguration signal 7 to cause the FPGA in which the error has occurred, to perform reconfiguration. The reconfiguration circuit 6 is constituted of only logic operation elements. Specifically, the reconfiguration signal 7 is a signal that causes an FPGA determined to be disagreeing by the majority decision circuit 5, to perform reconfiguration. The reconfiguration circuit 6 is also called reconfiguration signal generation circuit.

The reconfiguration signal 7 is a signal generated by the reconfiguration circuit 6. The reconfiguration signal 7 is a signal outputted to the FPGA1, the FPGA2, or the FPGA3 to conduct reconfiguration by the FPGA1, the FPGA2, or the FPGA3.

The input signal 8 is a signal to be inputted to each FPGA. The input signal 8 is inputted to IN of each FPGA via the output determination circuit 4.

The output signal 9 is an output signal determined as the output of the FPGA by the majority decision circuit 5. OUT1, OUT2, and OUT3 represent an output from the FPGA1, an output from the FPGA2, and an output from the FPGA3, respectively. The outputs OUT1, OUT2, and OUT3 of the FPGAs are inputted to the majority decision circuit 5, and determination by majority decision is performed. Then, the majority decision circuit 5 outputs the output signal 9 as a determination result. If an FGPA is determined to be disagreeing due to an error, the majority decision circuit 5 outputs the error signal ERR notifying in which FPGA the error has occurred.

The error signal ERR is a signal detected by the majority decision circuit 5. The error signal ERR notifies in which FPGA the error has occurred to the reconfiguration circuit 6.

For example, if an error has occurred in the FPGA1, the majority decision circuit 5 notifies the reconfiguration circuit 6 that an error has occurred in the FPGA1, by the error signal ERR. The reconfiguration circuit 6 transmits the reconfiguration signal 7 that effects reconfiguration, to the FPGA1 in which the error has occurred. The reconfiguration circuit 6 thus causes the FPGA1 to perform reconfiguration.

The output determination circuit 4 is formed of a hard-wired circuit. Each of the majority decision circuit 5 and reconfiguration circuit 6 mounted on the output determination circuit 4 does not employ RAMs, being memory elements, or flip-flops, but is constituted of only logic operation elements. Thus, in the output determination circuit 4, it is not necessary to consider a software error to a memory element. As a result, even if a software error occurs in the FPGA1, FPGA2, or FPGA3 and accordingly one output among the output signals OUT1, OUT2, and OUT3 becomes abnormal, a normal output signal 9 can be outputted by the majority decision circuit 5.

***Description of Operation***

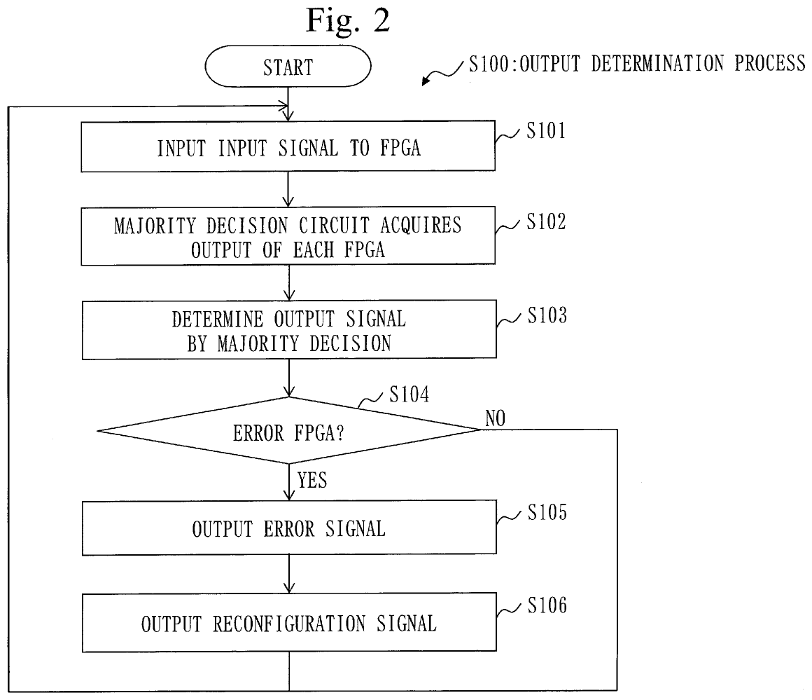

Output determination process S100 by the output determination circuit 4 according to the present embodiment will be described with referring to FIG. 2.

In step S101, the output determination circuit 4 inputs an input signal 8 to the FPGA1, FPGA2, and FPGA3.

In step 5102, the majority decision circuit 5 acquires the outputs OUT1, OUT2, and OUT3 of the FPGAs.

In step S103, the majority decision circuit 5 performs majority decision on the outputs of the plurality of FPGAs, thereby determining the outputs from the plurality of FPGAs as the output signal 9.

In step S104, it is checked whether there is an FPGA in which an error has occurred.

If there is an FPGA in which an error has occurred, then in step S105, the majority decision circuit 5 outputs the error signal ERR to notify in which FPGA the error has occurred among the plurality of FPGAs.

In step S106, the reconfiguration circuit 6 acquires the error signal ERR and outputs the reconfiguration signal 7 that effects reconfiguration, to the FPGA in which the error has occurred. Then, the reconfiguration circuit 6 causes the FPGA in which the error has occurred, to perform reconfiguration.

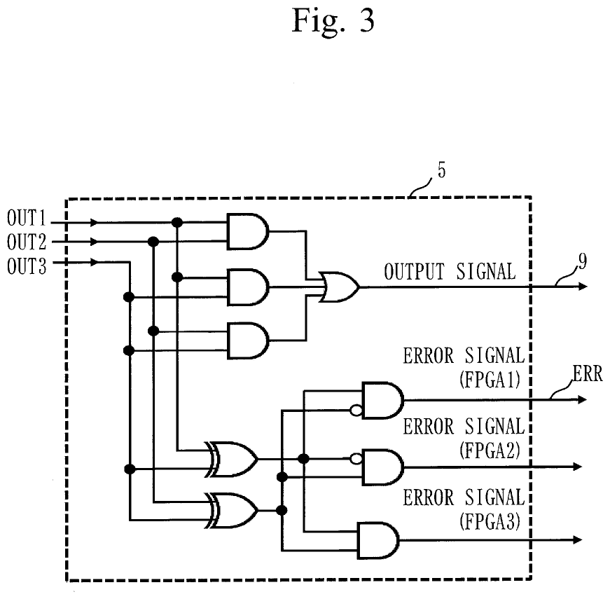

An example of the majority decision circuit 5 according to the present embodiment will be described with referring to FIG. 3.

The majority decision circuit 5 of FIG. 3 makes majority decision on the output signals OUT1, OUT2, and OUT3 of the respective FPGA1, FPGA2, and FPGA3 by means of a combination of AND circuits and OR circuits, and outputs a result to the output signal 9. The majority decision circuit 5 also checks agreement among the output signals OUT1, OUT2, and OUT3 by an XOR circuit. If there is disagreement, the majority decision circuit 5 generates an error signal ERR indicating a disagreeing FPGA. Then, the majority decision circuit 5 sends the error signal ERR to the reconfiguration circuit 6.

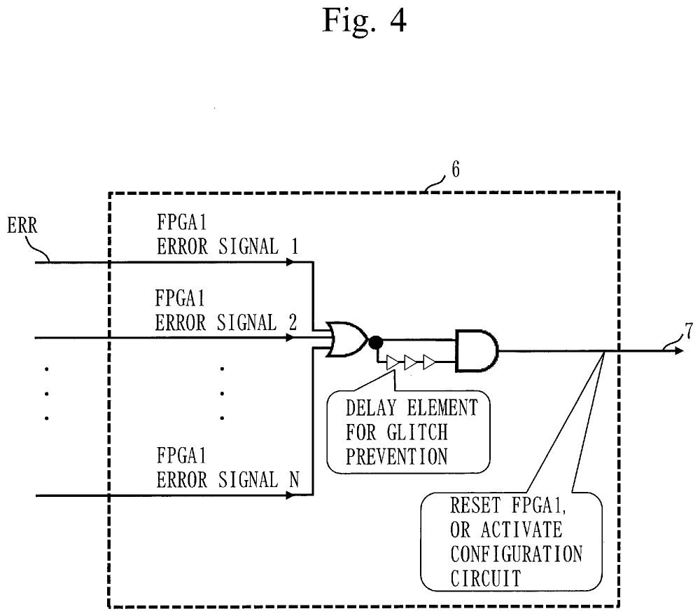

An example of the reconfiguration circuit 6 according to the present embodiment will be described with referring to FIG. 4. Upon reception of the error signal ERR, the reconfiguration circuit 6 generates the reconfiguration signal 7 that causes a corresponding FPGA to perform reconfiguration.

The reconfiguration circuit 6 of FIG. 4 calculates OR of a plurality of error signals ERR outputted from the majority decision circuit 5 and outputs an ORed result to the reconfiguration signal 7 via a circuit for deleting a glitch, that is, a glitch-preventing delay element. Assume that in FIG. 4, an error has occurred in the FPGA1. The reconfiguration circuit 6 outputs the reconfiguration signal 7 to reset the FPGA1 or activate a configuration circuit of the FPGA1.

***Other Configurations***

In the processing circuit 100 of the present embodiment, three FPGAs are employed as an example of the plurality of FPGAs, but this does not intend to limit the number of FPGAs to three. The presented number of FPGAs in the processing circuit 100 is merely exemplary, and the present embodiment can be applied as far as the number of FPGAs is an odd number.

Also, the processing circuit 100 of the present embodiment employs a plurality of FPGAs, but this does not intend to limit the present embodiment to employment of FPGAs. Circuits and devices of any type in which a software error may occur can be employed.

***Description of Effect of Embodiment***

The output determination circuit 4 according to the present embodiment is formed of a hard-wired circuit. Each of the majority decision circuit 5 and reconfiguration circuit 6 mounted on the output determination circuit 4 does not employ RAMs, being memory elements, or flip-flops, but is constituted of only logic operation elements. Thus, in the output determination circuit 4, it is not necessary to consider a software error to a memory element. As a result, even if a software error occurs in the FPGA1, FPGA2, or FPGA3 and accordingly one of OUT1, OUT2, and OUT3 becomes abnormal, a normal output signal can be accurately outputted by the majority decision circuit 5.

In this manner, since the output determination circuit 4 according to the present embodiment is fabricated by the hard-wired scheme, a RAM storing logic-circuit information as an FPGA is not employed, so that the output determination circuit 4 is not influenced by a software error. As the circuit is formed without using a memory element such as a flip-flop, the circuit is free from a possibility of data rewrite by cosmic radiation. Hence, the output determination circuit 4 can make majority decision on outputs of the plurality of FPGA without being influenced by cosmic radiation.

In the output determination circuit 4 according to the present embodiment, the majority decision circuit 5 detects an FPGA in which an error has occurred, and notifies the reconfiguration circuit 6 of this FPGA. Then, the reconfiguration circuit 6 can cause the FPGA in which the error has occurred, to perform reconfiguration. Each of the majority decision circuit 5 and reconfiguration circuit 6 does not employ RAMs, being memory elements, or flip-flops, but is constituted of only logic operation elements. Hence, with the processing circuit 100 according to the present embodiment, even if an error occurs in an FPGA, this FPGA can be caused to perform reconfiguration appropriately.

### Embodiment 2

In the present embodiment, a difference from Embodiment 1 will mainly be described.

In the present embodiment, the same configuration as in Embodiment 1 is denoted by the same reference sign, and its description is omitted.

In Embodiment 1, as the output determination circuit 4 is fabricated by hard wiring, INs to and OUTs from the FPGAs are fixed, and accordingly the degree of freedom of design is impaired. In view of this, a function is added in the present embodiment, in which bi-directional selectors are connected to the input/output pins of the FPGA1, FPGA2, and FPGA3, so that input/output directions can be selected as desired.

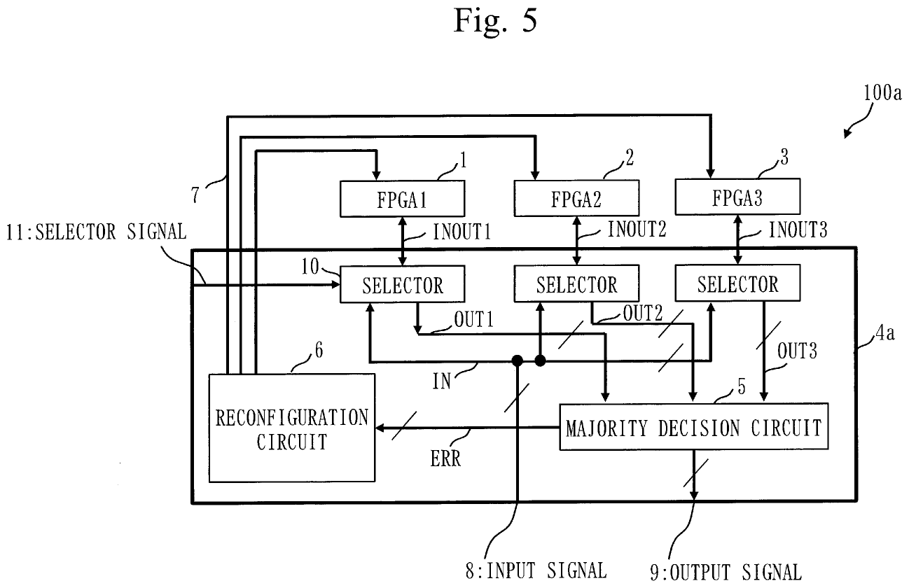

A processing circuit 100a according to the present embodiment will be described with referring to FIG. 5.

An FPGA1, an FPGA2, an FPGA3, a majority decision circuit 5, a reconfiguration circuit 6, a reconfiguration signal 7, an input signal 8, an output signal 9, and an error signal ERR are the same as their counterparts described in Embodiment 1.

Note that in the present embodiment, an input/output INOUT1, an input/output INPUT2, and an input/output INOUT3, each being an input/output pin, are connected to the FPGA1, FPGA2, and FPGA3, respectively.

An output determination circuit 4a is provided with a selector 10 which switches input/output of a signal connected to each of the plurality of FPGAs. The selector 10 is constituted of only logic operation elements. The selector 10 switches input/output of the signal connected to each of the plurality of FPGAs, by a selector signal 11.

The selector 10 connected to the input/output NOUT1 is a circuit that selects to which one, between IN and OUT1, to connect INOUT1 which is connected to the FPGA1. The selector signal 11 is a signal that controls the selector 10. The selector signal 11 is connected to a power supply or a GND and, by pull-up or pull-down, switches input/output of the signal connected to each of the plurality of FPGAs.

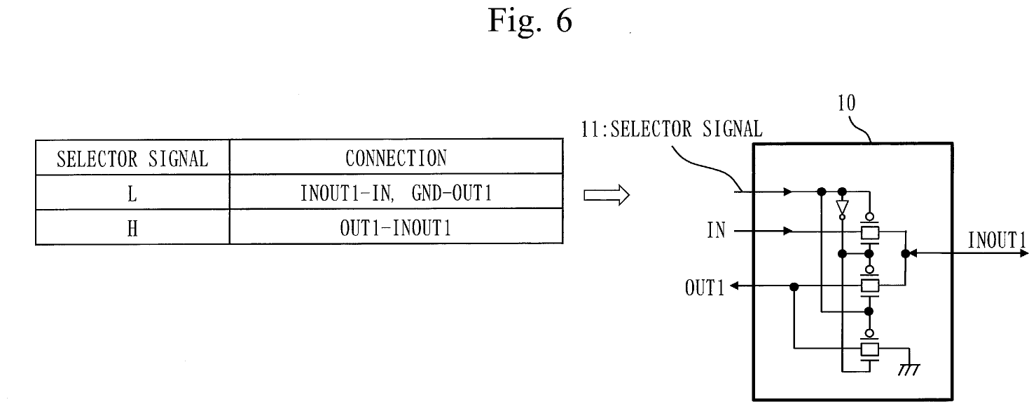

An example of the selector 10 according to the present embodiment will be described with referring to FIG. 6.

FIG. 6 illustrates a configuration of the selector 10 and connection of the selector 10 in each of a case where the selector signal 11 is L and a case where the selector signal 11 is H.

By connecting the selector signal 11 to the power supply of GND, to which one, between IN and OUT, to connect the FPGA1 for the FPGA1 can be selected. The circuit of the selector 10 does not employ a memory element, and accordingly is not influenced by a software error. The operation of the selector 10 is determined by pulling up or pulling down the selector signal 11, and accordingly is not influenced by a software error.

### Embodiment 3

In the present embodiment, a difference from Embodiment 2 will mainly be described.

In the present embodiment, the same configuration as in Embodiment 2 is denoted by the same reference sign, and its description is omitted.

In Embodiment 2, since the selector signal 11 is connected to the power supply or a GND, for the selector signal 11, terminals corresponding in number to input/output pins of the FPGAs are required. Accordingly, the number of terminals increases. In view of this, in the present embodiment, setting of the selector signal 11 can be performed on the side of the FPGAs.

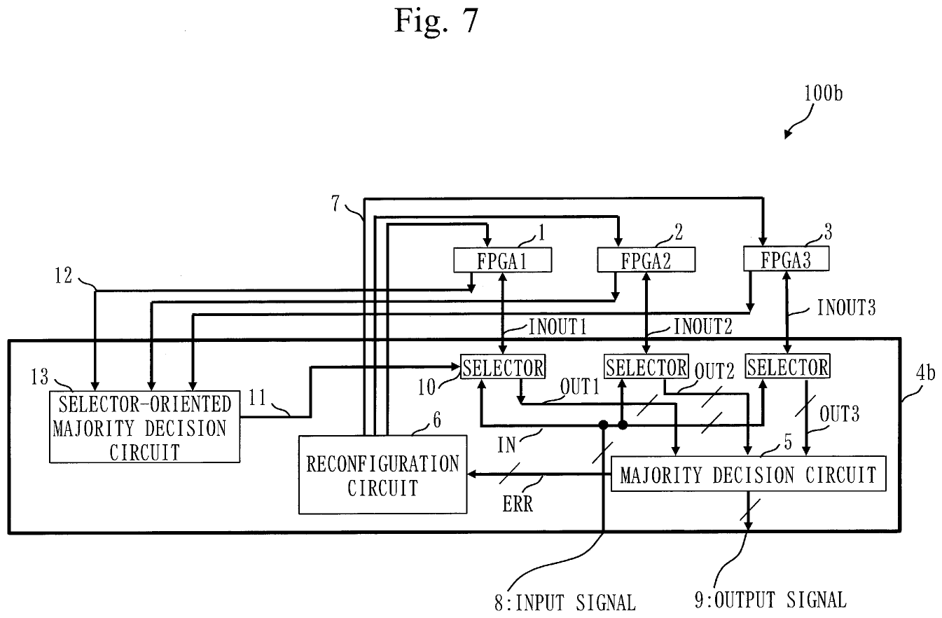

A processing circuit 100b according to the present embodiment will be described with referring to FIG. 7.

FPGA1, FPGA2, FPGA3, a majority decision circuit 5, a reconfiguration circuit 6, a reconfiguration signal 7, an input signal 8, an output signal 9, an error signal ERR, a selector 10, and a selector signal 11 are the same as those described in Embodiment 2.

In present embodiment, the selector signal 11 is set by the plurality of FPGAs. An output determination circuit 4b according to the present embodiment is provided with a selector-oriented majority decision circuit 13 to determine the selector signal 11 set by the plurality of FPGAs.

The selector-oriented majority decision circuit 13 acquires, from each of the plurality of FPGAs, a signal 12 to be inputted to the selector 10, and performs majority decision, thereby determining the selector signal 11 set by the plurality of FPGAs.

The signal 12 is outputted from each of the FGPA1, FPGA2, and FPGA3. The signal 12 is a signal corresponding to the selector signal 11 in Embodiment 2.

The selector-oriented majority decision circuit 13 is a circuit that decides on the signals 12 outputted from the FGPA1, FPGA2, and FPGA2, by majority decision. A circuit example of the selector-oriented majority decision circuit 13 is the same as the majority decision circuit 5. Decision is made on the signals 12 by majority decision. Therefore, even if the FPGA1, FPGA2, or FPGA3 is influenced by a software error and one output among the signals 12 becomes abnormal, a normal signal can be outputted by the selector-oriented majority decision circuit 13 as the selector signal 11.

### Embodiment 4

In the present embodiment, a difference from Embodiments 1 to 3 will mainly be described.

In the present embodiment, the same configuration as in Embodiments 1 to 3 is denoted by the same reference sign, and its description is omitted.

In Embodiments 1 to 3, each of the FPGA1, FPGA2, and FPGA3 is an independent FPGA. In recent years, an FPGA has been developed in which reconfiguration can be performed only for a specific area of the FPGA. In view of this, in the present embodiment, a processing circuit 100c will be described in which a plurality of FPGAs that perform the same operation are mounted on one FPGA14.

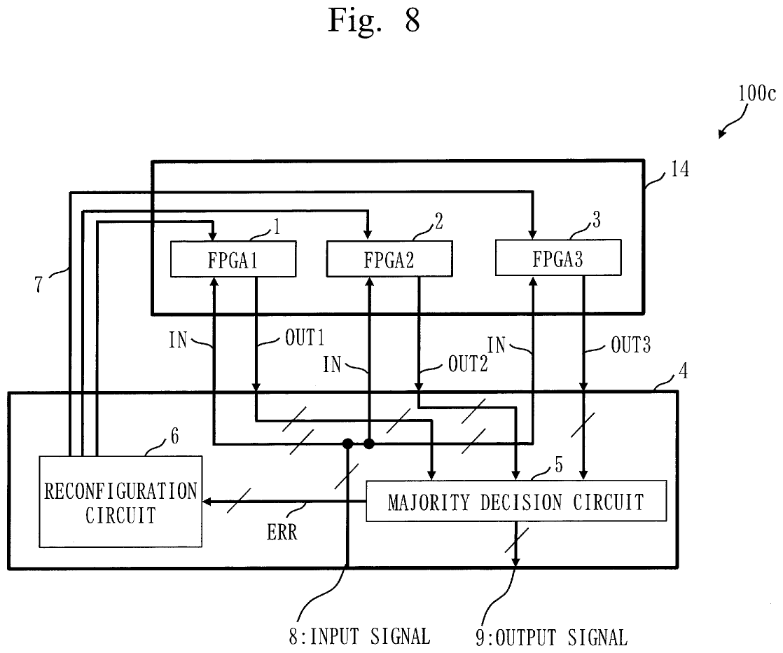

The processing circuit 100c according to the present embodiment will be described with referring to FIG. 8.

In the processing circuit 100c of FIG. 8, an odd number of FPGAs which perform the same operation are formed on one FPGA14. Other than this, the configuration is the same as that of Embodiment 1.

By forming the FPGA1, FPGA2, and FPGA3 as one FPGA14, a plurality of FPGAs can be formed as one FPGA14.

Even with the configuration as illustrated in FIG. 8, the same effect as that in Embodiment 1 can be achieved. When a configuration that implements the FPGA1, FPGA2, and FPGA3 by one FPGA is applied to Embodiment 2 or 3, the same effect as in Embodiment 2 or 3 can be achieved.

Of Embodiments 1 to 4, a plurality of portions may be practiced in combination. Alternatively, of these embodiments, one portion may be practiced. Furthermore, these embodiments may be practiced in any combination entirely or partially.

The embodiments described above are essentially preferable exemplifications and are not intended to limit the scope of the present invention, the scope of applied product of the present invention, and the scope of usage of the present invention. The embodiments described above can be modified in various manners as necessary.

### REFERENCE SIGNS LIST

1, 2, 3, 14: FPGA; 4, 4a, 4b: output determination circuit; 5: majority decision circuit; 6: reconfiguration circuit; 7: reconfiguration signal; 8: input signal; 9: output signal; ERR: error signal; 10: selector; 11: selector signal; 12: signal; 13: selector-oriented majority decision circuit; 100, 100a, 100b, 100c: processing circuit.

1.-6. (canceled)

7. An output determination circuit which is fabricated by a hard-wired scheme to execute an instruction via hardware connection, and which determines an output signal of a Field Programmable Gate Array (FPGA) which operates according to logic information, the output determination circuit comprising:
a majority decision circuit which is connected to outputs of a plurality of FPGAs that perform the same operation and which performs majority decision on the outputs of the plurality of FPGAs to determine the outputs from the plurality of FPGAs as the output signal, the majority decision circuit being constituted of only logic operation elements in which a software error and an error due to a flip-flop do not occur; and
a selector which switches input/output of a signal connected to each of the plurality of FPGAs, the selector being constituted of only logic operation elements.

8. The output determination circuit according to claim 7,
wherein the majority decision circuit outputs an error signal that notifies of in which FPGA an error has occurred among the plurality of FPGAs, and
wherein the output determination circuit comprises a reconfiguration circuit which, based on the error signal, outputs a reconfiguration signal to cause the FPGA in which the error has occurred, to perform reconfiguration, the reconfiguration circuit being constituted of only logic operation elements.

9. The output determination circuit according to claim 7,
wherein the selector switches input/output of the signal connected to each of the plurality of FPGAs by a selector signal, and
wherein the selector signal is connected to a power supply or a GND and, by pull-up or pull-down, switches input/output of the signal connected to each of the plurality of FPGAs.

10. The output determination circuit according to claim 8,
wherein the selector switches input/output of the signal connected to each of the plurality of FPGAs by a selector signal, and
wherein the selector signal is connected to a power supply or a GND and, by pull-up or pull-down, switches input/output of the signal connected to each of the plurality of FPGAs.

11. The output determination circuit according to claim 7,
wherein the selector switches input/output of the signal connected to each of the plurality of FPGAs by a selector signal,
wherein the selector signal is set by the plurality of FPGAs, and
wherein the output determination circuit comprises a selector-oriented majority decision circuit to acquire, from each of the plurality of FPGAs, a signal to be inputted to the selector, and to perform majority decision, thereby determining the selector signal set by the plurality of FPGAs.

12. The output determination circuit according to claim 8,
wherein the selector switches input/output of the signal connected to each of the plurality of FPGAs by a selector signal,
wherein the selector signal is set by the plurality of FPGAs, and
wherein the output determination circuit comprises a selector-oriented majority decision circuit to acquire, from each of the plurality of FPGAs, a signal to be inputted to the selector, and to perform majority decision, thereby determining the selector signal set by the plurality of FPGAs.

13. The output determination circuit according to claim 7, wherein the plurality of FPGAs are mounted on one FPGA.

14. The output determination circuit according to claim 8, wherein the plurality of FPGAs are mounted on one FPGA.

15. The output determination circuit according to claim 9, wherein the plurality of FPGAs are mounted on one FPGA.

16. The output determination circuit according to claim 10, wherein the plurality of FPGAs are mounted on one FPGA.

17. The output determination circuit according to claim 11, wherein the plurality of FPGAs are mounted on one FPGA.

18. The output determination circuit according to claim 12, wherein the plurality of FPGAs are mounted on one FPGA.
